(19) United States
(12) Patent Application Publication
(10) Pub. No.: US 2021/0036489 A1
(43) Pub. Date: Feb. 4, 2021

(54) NARROW LINEWIDTH EXTERNAL CAVITY LASER AND OPTICAL MODULE

(71) Applicant: InnoLight Technology (Suzhou) LTD., Suzhou (CN)

(72) Inventors: Wenkai TU, Suzhou (CN); Liang LUO, Suzhou (CN)

(21) Appl. No.: 16/944,411

(22) Filed: Jul. 31, 2020

(30) Foreign Application Priority Data
Aug. 2, 2019 (CN) 201910712122.6
Aug. 2, 2019 (CN) 201910712733.0

(51) Int. Cl. H01S 5/14; H01S 5/022; H01S 5/00; H01S 5/024

(52) U.S. Cl. CPC H01S 5/141; H01S 5/02288; H01S 5/02284; H01S 5/02415; H01S 5/0064

(57) ABSTRACT

A narrow linewidth external cavity laser includes a sealed housing, an external resonant cavity disposed in the sealed housing, and a gain chip and a tunable wavelength selective component disposed in the external resonant cavity. An electrical interface of the sealed housing is configured to receive an electrical signal such as a drive signal, a wave selection signal, a cavity length control signal, and a dither control signal. The cavity length control signal is configured to adjust an optical cavity length of the external resonant cavity so that a laser mode produced in the external resonant cavity aligns with a wavelength selected by the wavelength selective component. The dither control signal is configured to control the optical cavity length of the external resonant cavity to produce dither by adjusting an optical length of the gain chip in order to lock a center wavelength of an output light beam.

### CROSS-REFERENCE TO RELATED APPLICATION

This application is based upon and claims priority to Chinese Patent Application 201910712122.6, filed on Aug. 2, 2019, and Chinese Patent Application 201910712733.0, filed on Aug. 2, 2019. The entire contents of these applications are incorporated herein by reference.

### FIELD OF THE DISCLOSURE

The present disclosure relates to the field of optical communication technology and, more particularly, to a narrow linewidth external cavity laser and an optical module including the narrow linewidth external cavity laser.

### BACKGROUND

In the field of optical communication, coherent optical communication is an important technology for addressing the problem of dispersion during long distance transmission. A core part of a coherent optical transmitter is a wavelength tunable laser. In particular, a tunable external cavity laser, characterized by its narrow linewidth, is very good for addressing the problem of dispersion during long distance transmission.

Smaller packages have been a trend in the development of tunable lasers and are required to be adapted for optical modules in various different package forms. Chinese Application No. 201410059069.1 discloses a small packaged tunable laser having a housing smaller than 0.6 cm³ in volume, the housing having disposed therein, sequentially, a tunable semiconductor laser, a beam splitter, an optical isolator, a photodiode, and a coupling optical system. The tunable semiconductor laser includes a gain chip, a Vernier tuning mechanism made of two filters, and a cavity length actuator. Increasing the level of integration in devices requires that optical modules become smaller in volume. Therefore, lasers, as core parts of coherent optical modules, are subjected to the requirement of decreasing volume. The tunable laser assembly disclosed in the aforementioned patent application has a relatively small volume; however, it is clear that the volume of the tunable laser assembly need to be smaller for some smaller optical modules.

### SUMMARY

Purposes of the present disclosure include providing a narrow linewidth external cavity laser and an optical module that offer advantages such as small package size, low insertion loss, and narrow laser light linewidth.

To achieve one or more of the aforementioned purposes, one embodiment of the present disclosure provides a narrow linewidth external cavity laser including a sealed housing having disposed thereon an optical interface and an electrical interface, an external resonant cavity disposed in the sealed housing, and a gain chip and a tunable wavelength selective component disposed in the external resonant cavity. The electrical interface is configured to receive an electrical signal including a drive signal, a wave selection signal, a cavity length control signal, and a dither control signal. The drive signal is configured to drive the gain chip to emit a light beam, the light beam resonating in the external resonant cavity to produce a laser mode. The wave selection signal is configured to tune the wavelength selective component to select a wavelength. The cavity length control signal is configured to adjust an optical cavity length of the external resonant cavity so that the laser mode aligns with the wavelength selected by the wavelength selective component. The dither control signal is configured to control the optical cavity length of the external resonant cavity to produce dither by adjusting an optical length of the gain chip, in order to lock a center wavelength of an output light beam.

Another embodiment of the present disclosure provides a narrow linewidth external cavity laser including a sealed housing having disposed thereon an optical interface and an electrical interface, an external resonant cavity disposed in the sealed housing, and a gain chip and a tunable wavelength selective component that are disposed in the external resonant cavity. The electrical interface is configured to receive an electrical signal comprising a drive signal, a wave selection signal, a cavity length control signal, and a dither control signal. The drive signal is configured to drive the gain chip to emit a light beam, the light beam resonating in the external resonant cavity to produce a laser mode. The wave selection signal is configured to tune the wavelength selective component to select a wavelength. The cavity length control signal is configured to adjust an optical cavity length of the external resonant cavity so that the laser mode aligns with the wavelength selected by the wavelength selective component. The dither control signal is configured to control the optical cavity length of the external resonant cavity to produce dither in order to lock the center wavelength of an output light beam. The cavity length control signal is configured to adjust the optical cavity length of the external resonant cavity by adjusting an optical length of the gain chip.

Still another embodiment of the present disclosure provides an optical module including the external cavity laser of any one of the aforementioned example embodiments.

### BRIEF DESCRIPTION OF THE DRAWINGS

FIG. 1 is a diagram illustrating a package of a narrow linewidth external cavity laser package according to an example embodiment of the present disclosure.

FIG. 2 is a diagram illustrating a laser assembly of an external cavity laser according to a first example embodiment of the present disclosure.

FIG. 3 is a diagram illustrating a cavity length control signal and a dither control signal acting on a gain chip according to the first example embodiment of the present disclosure.

FIG. 4 is a diagram illustrating a cavity length control signal acting on a thermoelectric cooler (TEC) according to a variation of the first example embodiment of the present disclosure.

FIG. 5 is a diagram illustrating a cavity length control signal acting alone on a gain chip according to a second example embodiment of the present disclosure.

FIG. 6 is a diagram illustrating a dither control signal acting alone on a gain chip according to a variation of the second example embodiment of the present disclosure.

FIG. 7 is a diagram illustrating a cavity length control signal acting alone on a gain chip according to a third example embodiment of the present disclosure.

FIG. 8 is a diagram illustrating a dither control signal acting alone on a gain chip according to a variation of the third example embodiment of the present disclosure.

FIG. 9 is a diagram illustrating a laser assembly of an external cavity laser according to a fourth example embodiment of the present disclosure.

FIG. 10 is a diagram illustrating a package of a narrow linewidth external cavity laser package according to an example embodiment of the present disclosure.

FIG. 11 is a structural diagram illustrating an optical module according to an example embodiment of the present disclosure.

### DETAILED DESCRIPTION

The text below provides a detailed description of the present disclosure with reference to specific embodiments illustrated in the attached drawings. However, these embodiments do not limit the present disclosure; the scope of protection for the present disclosure covers changes made to the structure, method, or function by persons having ordinary skill in the art on the basis of these embodiments.

In order to facilitate the presentation of the drawings in the present disclosure, the sizes of certain structures or portions have been enlarged relative to other structures or portions; therefore, the drawings in the present application are only for the purpose of illustrating the basic structure of the subject matter of the present application.

Additionally, terms in the text indicating relative spatial position, such as “upper,” “above,” “lower,” “below,” and so forth, are used for explanatory purposes in describing the relationship between a unit or feature depicted in a drawing with another unit or feature therein. Terms indicating relative spatial position may refer to positions other than those depicted in the drawings when a device is being used or operated. For example, if a device shown in a drawing is flipped over, a unit which is described as being positioned “below” or “under” another unit or feature will be located “above” the other unit or feature. Therefore, the illustrative term “below” may include positions both above and below. A device may be oriented in other ways (rotated 90 degrees or facing another direction), and descriptive terms that appear in the text and are related to space should be interpreted accordingly. When an element or layer is said to be “above” another component or layer or “connected to” another component or layer, it may be directly above the other component or layer or directly connected to the other component or layer, or there may be an intermediate element or layer.

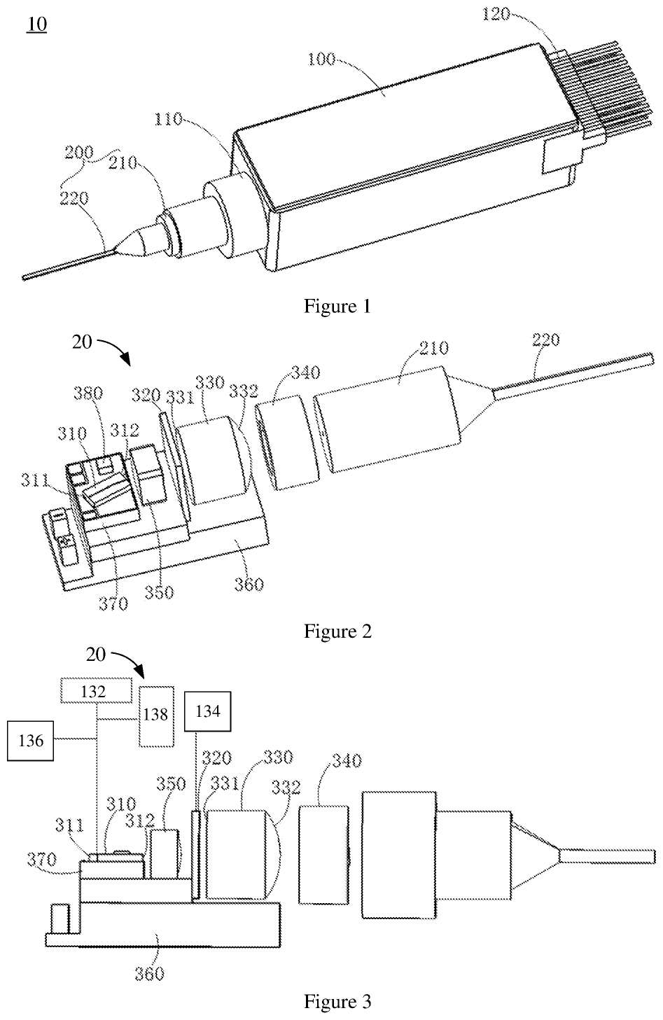

Embodiments of the present disclosure provide a narrow linewidth external cavity laser having a small package size. FIG. 1 is a diagram illustrating a package of a narrow linewidth external cavity laser 10, according to an embodiment of the present disclosure. FIG. 2 is a diagram illustrating a laser assembly 20 of the external cavity laser 10 of FIG. 1 according to a first example embodiment of the present disclosure. FIG. 3 is a diagram illustrating a cavity length control signal and a dither control signal acting on a gain chip according to the first example embodiment. As illustrated in FIGS. 1 and 2, the external cavity laser 10 includes a sealed housing 100 and the laser assembly 20 disposed in the sealed housing 100. The laser assembly 20 includes an external resonant cavity, as well as a gain chip 310 and a tunable wavelength selective component 320 that are disposed in the external resonant cavity. The sealed housing 100 includes an optical interface 110 and an electrical interface 120, the optical interface 110 being used to transmit an optical signal, and the electrical interface 120 being used to receive electrical signals. With reference to FIG. 3, the electrical signal received by the electrical interface 120 includes a drive signal, a wave selection signal 134, the cavity length control signal 136, and the dither control signal 138. During operation, the drive signal, such as a bias current 132 applied to the gain chip 310, drives the gain chip 310 to emit a light beam, which resonates in the external resonant cavity to produce a laser mode. The wave selection signal 134 tunes the wavelength selective component 320 to select a needed wavelength. For example, a certain International Telecommunication Union (ITU) standard wavelength needed for optical communication may be selected. The cavity length control signal 136 is used to adjust an optical cavity length of the external resonant cavity to change the phase of the laser mode so that the aforementioned laser mode aligns with the wavelength selected by the wavelength selective component 320. The dither control signal 138 is used to control the optical cavity length of the external resonant cavity to produce dither, thereby causing the center wavelength of an output light beam to dither. The dithering of the center wavelength of the output light beam is detected by a Monitor Photo Diode (MPD), which is disposed outside or inside of the housing 100, and fed back to a controller that controls cavity length control signal 136, so that the controller may finely adjust the cavity length control signal 136 according to the detected dithering in order to lock a center wavelength of the output light beam that is needed.

One or both of the aforementioned cavity length control signal 136 and dither control signal 138 are applied to adjust the optical length of the gain chip 310 and thereby adjust the optical cavity length of the external resonant cavity and/or cause the optical cavity length to dither. By having the cavity length control signal 136 act on the gain chip 310, the number of components in the external cavity is decreased, which significantly reduces the package size, resulting in a smaller volume. Also, insertion loss in the external cavity may be effectively reduced, thus decreasing the impact of insertion loss on the power and linewidth of the laser 10, thereby resulting in stabler output laser light with a narrower linewidth. The following example embodiments describe the specific structure of the laser assembly 20 in the housing 100 with reference to the attached drawings.

### First Example Embodiment

As illustrated in FIGS. 1 through 3, the laser assembly 20 disposed in the sealed housing 100 includes the external resonant cavity, as well as the gain chip 310 and the tunable wavelength selective component 320 that are disposed in the external resonant cavity. Also disposed in the sealed housing 100 are a coupling lens 330 and an isolator 340. The optical interface 110 of the sealed housing 100 is connected to an optical fiber 200. Laser light outputted from the laser assembly 20 is coupled into the optical fiber 200 through the coupling lens 330 and is transmitted outside of the housing 100 by the optical fiber 200. The aforementioned optical fiber 200 includes a fiber optic head 210 and a pigtail 220. The fiber optic head 210 includes a securing sleeve, such as a glass sleeve. A capillary is disposed in the securing sleeve. One end of the pigtail 220 is disposed in the capillary. The securing sleeve of the fiber optic head 210 is disposed in the optical interface 110 of the housing 100. With the fiber optic head 210, no ceramic ferrule is needed, as the glass sleeve is used directly to secure the pigtail, thus shortening the length of the fiber optic head 210 and reducing the overall size of the laser 10. In another example embodiment, the optical interface 110 of the housing 100 may alternatively connect to a pluggable connector and does not have to connect to an optical fiber.

In the first example embodiment, a thermoelectric cooler (TEC) 360 and a thermistor 380 are further disposed in the housing 100. The aforementioned gain chip 310, wavelength selective component 320, and coupling lens 330 are disposed on the TEC 360. The gain chip 310 is disposed on the TEC 360 by means of a chip substrate 370. In other words, the gain chip 310 is disposed on the chip substrate 370 which is disposed on the TEC 360. The thermistor 380 is disposed on the chip substrate 370 and near the gain chip 310, and is used to provide feedback about the temperature of the gain chip 310. The isolator 340 is disposed in the optical interface 110 of the housing 100. The external resonant cavity includes a first cavity surface and a second cavity surface. A first end surface 311 of the gain chip 310 away from the wavelength selective component 320 is coated with a highly reflective coating to serve as a reflective cavity surface of the external resonant cavity. A second end surface 312 of the gain chip 310 near the wavelength selective component 320 is coated with an anti-reflective coating. The coupling lens 330 includes a first flat surface 331 and a convex surface 332 that are located along an optical path. The first flat surface 331 is near the wavelength selective component 320 and is coated with a partially reflective coating to serve as an output cavity surface of the external resonant cavity. The convex surface 332 is a spherical or aspherical surface and is coated with an anti-reflective coating. In other words, the first end surface 311 of the gain chip 310 and the first flat surface 331 of the coupling lens 330 form two cavity surfaces of the external resonant cavity. For example, the first end surface 311 of the gain chip 310 forms the first cavity surface, and the first flat surface 331 of the coupling lens 330 forms the second cavity surface. In the first example embodiment, a collimating lens 350 is further disposed between the gain chip 310 and the wavelength selective component 320. The collimating lens 350 collimates a light beam emitted by the gain chip 310 onto the wavelength selective component 320, which selects a needed wavelength so that the needed wavelength wins a mode competition in the external resonant cavity, and resonates in the external resonant cavity to produce laser light. Finally, narrow linewidth single mode laser light is outputted through the aforementioned output cavity surface 331. The output laser light is focused and coupled into the optical fiber 200 by the coupling lens 330 to be outputted by the optical fiber 200. The isolator 340 disposed in the optical interface 110 isolates return light reflected from an end surface of the optical fiber 200 and various end surfaces along an external optical path, thereby preventing the return light from going back into the resonant cavity to impact the stability of the output laser light.

In the structure of the first example embodiment, two cavity surfaces of the external resonant cavity are integrated onto one end of the gain chip 310 and one end of the coupling lens 330, respectively. As a result, the number of optical components in the cavity is reduced effectively, thus not only decreasing insertion loss in the cavity, which further decreases the impact of insertion loss on the laser power and linewidth, but also effectively reducing the cavity length of the external cavity. The shorter the cavity length is, the larger the free spectral range (FSR) of the laser mode (cavity mode) of the resonance in the cavity, and the stabler the output laser light, which is less prone to mode hopping. Additionally, the shorter the cavity length is, the smaller the laser package may be made. Furthermore, the isolator 340 is integrated into the optical interface 110 (or optical window) of the housing 100 or into the fiber optic head 210 of the aforementioned optical fiber 200, thus further reducing the number of components in the housing 100 and enabling an even smaller housing 100. In the first example embodiment, the housing 100 may be made less than or equal to 3 cm³. For example, the housing may be made into a cuboid that is 10 mm long, 5.8 mm wide, and 4.4 m high, or even smaller.

In the first example embodiment, as illustrated in FIG. 3, the aforementioned cavity length control signal 136 and dither control signal 138 are both superimposed on the bias current 132 applied to the gain chip 310 to adjust the bias current of the gain chip 310, and thereby change an optical length of the gain chip 310, in order to adjust the optical cavity length of the external resonant cavity and cause the optical cavity length to dither. The refractive index and temperature of the gain chip 310 change as the strength of the bias current 132 applied to the gain chip 310 changes. A change in the refractive index of the gain chip 310 will cause the optical length of the gain chip 310 to change, and a change in the temperature of the gain chip 310 will also cause the optical length of the gain chip 310 to change, so that the optical cavity length of the external resonant cavity can be changed. In operation, the wave selection signal 134 tunes a transmission spectrum of the wavelength selective component 320 and switches the transmission spectrum to a wavelength (channel) needed. The cavity length control signal 136 is imposed on the bias current of the gain chip 310 to adjust the cavity length of the external resonant cavity, thereby changing the phase of the laser mode so that the output laser mode aligns with the wavelength selected by the wavelength selective component 320. The dither control signal 138 is added to the bias current to cause the optical cavity length of the external resonant cavity to dither and thereby cause the center wavelength of an output light beam to dither. The dithering of the center wavelength of the output light beam is fed back to the controller which may finely adjust the cavity length control signal 136 in order to lock the center wavelength of the output light beam that is needed. For example, the dither of the optical cavity length of the external resonant cavity will cause the center wavelength of the output light beam to dither, and a Monitor Photo Diode (MPD) outside the laser 10 will detect the dithering of the center wavelength of the output light beam and feed back the detected dithering to the controller that controls the cavity length control signal 136, so that the controller may finely adjust the cavity length control signal 136 according to the detected dithering in order to lock the center wavelength of the output light beam that is needed.

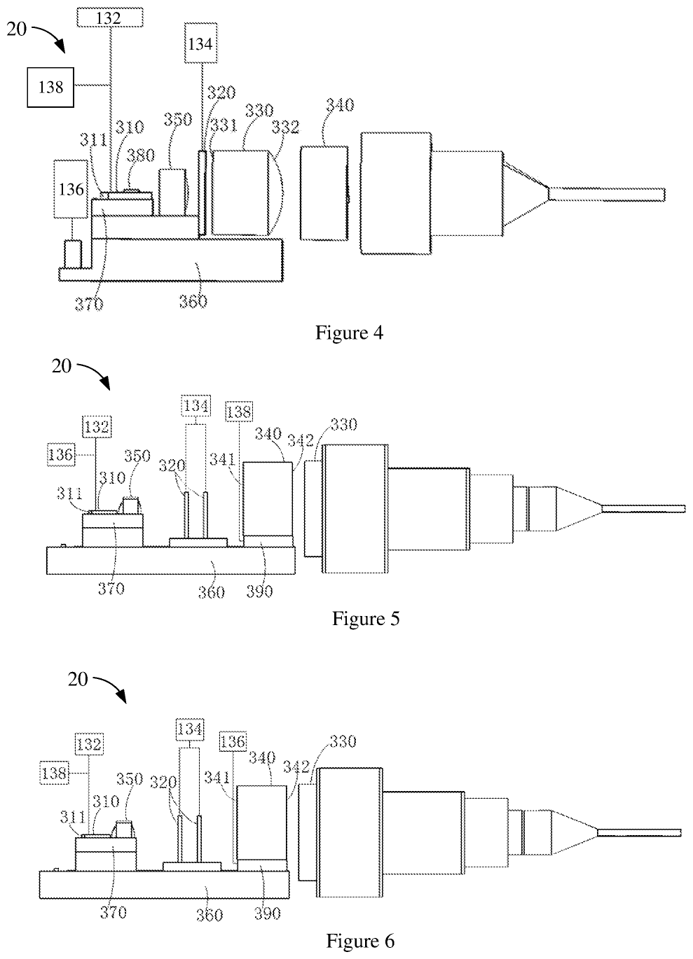

FIG. 4 is a diagram illustrating the cavity length control signal 136 acting on the TEC 360, according to a variation of the first example embodiment of the present disclosure. As illustrated in FIG. 4, the cavity length control signal 136 may be imposed on the TEC 360 to adjust the temperature of the TEC 360 and thereby change the temperature of the gain chip 310, in order to adjust the cavity length of the external resonant cavity to change the phase of the laser mode so that the output laser mode aligns with the wavelength selected by the wavelength selective component 320. The aforementioned gain chip 310 is disposed on the TEC 360 by means of the chip substrate 370. The thermistor 380 is disposed on the chip substrate 370 and is used to provide feedback about the temperature of the gain chip 310 and form a closed loop feedback system together with the TEC 360 to control the temperature of the gain chip 310.

One or both of the aforementioned cavity length control signal 136 and dither control signal 138 act on the gain chip to adjust the optical length of the gain chip 310 and thereby adjust the optical cavity length of the external resonant cavity and/or cause the optical cavity length to dither. This results in quick adjustment and eliminates the need for an additional adjusting component, thus reducing the number of components in the external cavity and further reducing the package size.

### Second Example Embodiment

FIG. 5 is a diagram illustrating the cavity length control signal 136 acting alone on the gain chip 310 according to a second example embodiment of the present disclosure. As illustrated in FIG. 5, the second example embodiment differs from the first example embodiment in that the aforementioned laser assembly 20 further includes an actuator 390. One cavity surface, such as the second cavity surface, of the external resonant cavity is disposed on the actuator 390. The aforementioned dither control signal 138 is imposed on the actuator 390 to adjust the actuator 390, thereby causing the cavity surface of the external resonant cavity on the actuator 390 to dither so that the output optical signal dithers, thus facilitating the locking of the center wavelength of the output light beam. The actuator 390 may be a piezoelectric component, an acousto-optical component, an electro-optical component, a liquid crystal assembly, a MEMS, or another linear electric motor, etc.

In the second example embodiment, the positions of the isolator 340 and the coupling lens 330 are different from those in the first example embodiment: the positions of the isolator 340 and the coupling lens 330 are swapped, the isolator 340 being disposed behind the wavelength selective component 320, the coupling lens 330 being integrated in the optical interface 110 of the sealed housing 100. The isolator 340 includes two opposing flat surfaces: a first flat surface 341 and a second flat surface 342 located along an output optical path of the external resonant cavity. The aforementioned second cavity surface serving as the output cavity surface of the external resonant cavity is disposed at the first flat surface 341 of the isolator 340 near the wavelength selective component 320. The isolator 340 is disposed on the aforementioned actuator 390, such as a piezoelectric ceramic (PZT), and the dither control signal 138 is imposed on the piezoelectric ceramic to control the deformation of the piezoelectric ceramic and thereby adjust the position of the output cavity surface disposed at the isolator 340, in order to cause the output cavity surface of the external resonant cavity to dither so that the output optical signal dithers, thus facilitating the locking of the center wavelength of the output light beam.

Alternatively, the positions of the coupling lens 330 and the isolator 340 may be the same as those in the first example embodiment 1: the coupling lens 330 is disposed on the actuator 390, and the dither control signal 138 is imposed on the actuator 390 to control the deformation of the actuator 390 and thereby adjust the position of the output cavity surface disposed at the coupling lens 330, in order to cause the output cavity surface to dither so that the output optical signal dithers, thus facilitating the locking of the center wavelength of the output light beam.

In another example embodiment, alternatively, an actuator, such as a piezoelectric ceramic (PZT) or another piezoelectric component, acousto-optical component, or electro-optical component that has good thermal conductivity, may be added below the gain chip 310. The gain chip 310 and the collimating lens 350 are both placed on the actuator, the actuator is then placed on the TEC 360, and the dither control signal 138 is imposed on the actuator to control the deformation of the actuator and thereby adjust the position of the cavity surface disposed at an end surface of the gain chip, in order to cause the cavity surface of the external resonant cavity to dither so that the output optical signal dithers, thus facilitating the locking of the center wavelength of the output light beam.

FIG. 6 is a diagram illustrating the dither control signal 138 acting alone on the gain chip 310 according to a variation of the second example embodiment of the present disclosure. As illustrated in FIG. 6, the dither control signal 138 is imposed on the bias current 132 applied to the gain chip 310, and the cavity length control signal 136 is imposed on the aforementioned actuator 390 (e.g. a piezoelectric ceramic, etc.). The components in FIG. 6 are the same as those in FIG. 5, the only difference between these two variations of the second example embodiment is that the cavity length control signal 136 and the dither control signal 138 perform control in different manners. In operation, the wave selection signal 134 tunes the transmission spectrum of the wavelength selective component 320 and switches the transmission spectrum to a wavelength (channel) needed. The cavity length control signal 136 is applied to the actuator 390 to control its deformation and thereby change the position of the output cavity surface, which is the first flat surface 341 of the isolator 340 disposed on the actuator 390, in order to adjust the cavity length of the external resonant cavity and thereby change the phase of the laser mode so that the output laser mode aligns with the wavelength selected by the wavelength selective component 320. The dither control signal 138 is added to the bias current 132 applied to the gain chip 310, thus causing the optical cavity length of the external resonant cavity to dither and then causing the center wavelength of an output light beam to dither. The dithering of the center wavelength of the output light beam is fed back to the controller that may finely adjust the cavity length control signal 136 according to the dithering in order to lock the center wavelength of the output light beam that is needed.

### Third Example Embodiment

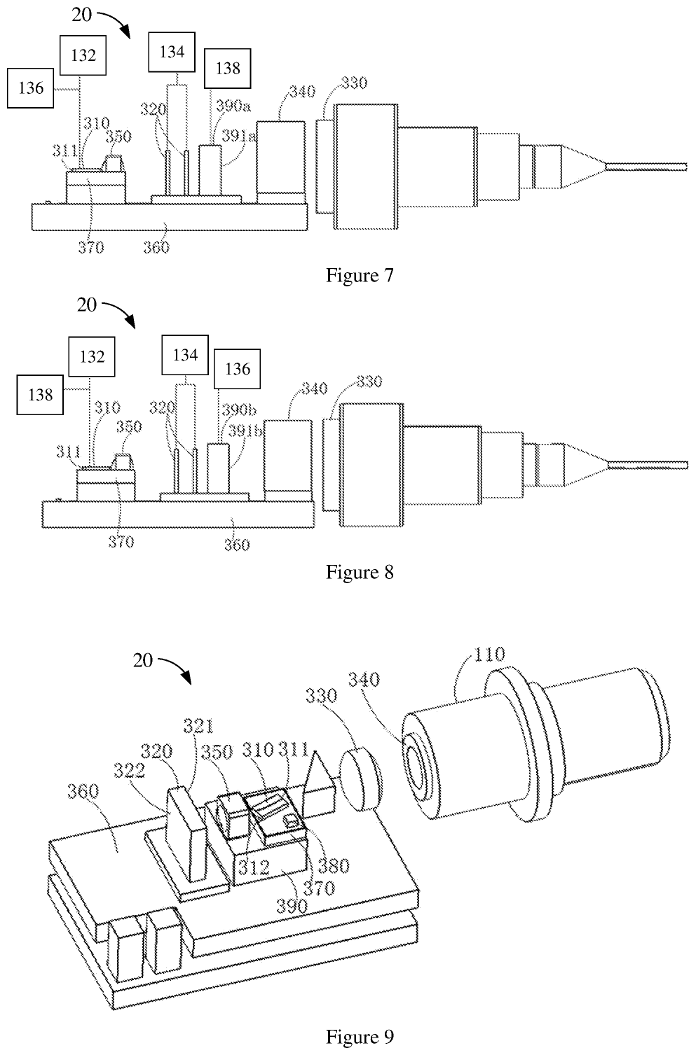

FIG. 7 is a diagram illustrating the cavity length control signal 136 acting alone on the gain chip 310 according to a third example embodiment of the present disclosure. As illustrated in FIG. 7, the third example embodiment differs from the second example embodiment in that there is no actuator in the laser assembly 20 in the third example embodiment. Instead, a cavity length dither component 390a is disposed in the external resonant cavity. The output cavity surface of the external resonant cavity may be disposed at a flat surface of the isolator 340 or at a flat surface 391a of the cavity length dither component 390a away from the wavelength selective component 320. The isolator 340 and the coupling lens 330 are disposed behind the output cavity surface of the external resonant cavity. In the third example embodiment, the output cavity surface of the external resonant cavity is disposed at the flat surface 391a of the cavity length dither component 390a away from the wavelength selective component 320, and the isolator 340 and the coupling lens 330 are disposed behind the cavity length dither component 390a. The dither control signal 138 is imposed on the cavity length dither component 390a to control the cavity length dither component 390a and thereby cause the external resonant cavity to produce optical dither so that the output optical signal dithers, thus facilitating the locking of the center wavelength of the output light beam. Here, the cavity length dither component 390a may include one of an acousto-optical component, a magnetic-optical component, an electro-optical component, or a liquid crystal assembly. The cavity length dither component 390a responds quickly to the dither control signal 138 and helps to increase wavelength locking efficiency and reduce power consumption. In operation, the cavity length control signal 136 is imposed on the bias current 132 applied to the gain chip 310 to adjust the bias current and thereby change the refractive index and temperature of the gain chip 310, in order to change the cavity length of the external resonant cavity and thereby change the phase of the laser mode so that the output laser mode aligns with the wavelength selected by the wavelength selective component 320. The dither control signal 138 is imposed on the cavity length dither component 390a, thus causing the optical cavity length of the external resonant cavity to dither and thereby causing the center wavelength of an output light beam to dither. The dithering of the center wavelength of the output light beam is fed back to the controller which may finely adjust the cavity length control signal 136 according to the dithering in order to lock the center wavelength of the output light beam that is needed.

FIG. 8 is a diagram illustrating the dither control signal 138 acting alone on the gain chip 310 according to a variation of the third example embodiment of the present disclosure. As illustrated in FIG. 8, the aforementioned cavity length dither component 390a may be replaced with a cavity length adjusting component 390b, and the aforementioned cavity length control signal 136 is imposed on the cavity length adjusting component 390b to control the cavity length adjusting component 390b and thereby change the optical cavity length of the external resonant cavity. The aforementioned dither control signal 138 is imposed on the bias current 132 applied to the gain chip 310 to adjust the bias current 132 and thereby change the refractive index and temperature of the gain chip 310, thus causing the optical cavity length of the external resonant cavity to dither and then causing the center wavelength of an output light beam to dither. The dithering of the center wavelength of the output light beam is fed back to the controller which may finely adjust the cavity length control signal 136 according to the dithering in order to lock the center wavelength of the output light beam that is needed. The cavity length adjusting component 390b may include one of a thermo-optical component, an acousto-optical component, a magnetic-optical component, an electro-optical component, or a liquid crystal assembly. The cavity surface of the external resonant cavity may be disposed at a flat surface of the isolator 340 or at a flat surface 391b of the cavity length adjusting component 390b away from the wavelength selective component 320. In the example embodiment illustrated in FIG. 8, the cavity length adjusting component 390b is disposed between the wavelength selective component 320 and the cavity surface of the external resonant cavity. The cavity length adjusting component 390b includes two opposing flat surfaces, and the cavity surface of the external resonant cavity is disposed at the flat surface 391b of the cavity length adjusting component 390b away from the wavelength selective component 320. In operation, the cavity length control signal 136 is imposed on the cavity length adjusting component 390b to change the cavity length of the external resonant cavity, thus changing the phase of the laser mode so that the output laser mode aligns with the wavelength selected by the wavelength selective component 320. The dither control signal 138 is imposed on the bias current 132 applied to the gain chip 310 to adjust the bias current 132 and thereby change the refractive index and temperature of the gain chip 310, thus causing the optical cavity length of the external resonant cavity to dither and then causing the center wavelength of an output light beam to dither. The dithering of the center wavelength of the output light beam is fed back to the controller which may adjust the cavity length control signal 136 according to the dithering in order to lock the center wavelength of the output light beam.

### Fourth Example Embodiment

FIG. 9 is a diagram illustrating the laser assembly 20 of the external cavity laser 10 according to a fourth example embodiment of the present disclosure. As illustrated in FIG. 9, the fourth example embodiment differs from the first and second example embodiments in that the first end surface 311 of the gain chip 310 away from the wavelength selective component 320 is coated with a partially reflective coating to serve as the output cavity surface of the external resonant cavity, and a flat surface 322 of the wavelength selective component 320 away from the gain chip 310 is coated with a highly reflective coating to serve as the reflective cavity surface of the external resonant cavity. The coupling lens 330, isolator 340, and optical interface 110 of the housing 100 are located along an output optical path of the output cavity surface of the gain chip 310.

In the fourth example embodiment, the cavity length control signal 136 and the dither control signal 138 may both be imposed on the bias current 132 applied to the gain chip 310. Alternatively, the cavity length control signal 136 may be imposed on the TEC 360 to change the refractive index and/or temperature of the gain chip 310, in order to adjust the cavity length of the external resonant cavity and thereby change the phase of the laser mode so that the output laser mode aligns with the wavelength selected by the wavelength selective component 320. The dither control signal 138 causes the optical cavity length of the external resonant cavity to dither and thereby causes the center wavelength of an output light beam to dither. The dithering of the center wavelength of the output light beam is fed back to the controller which may finely adjust the cavity length control signal 136 according to the dithering in order to lock the center wavelength of the output light beam that is needed.

Still alternatively, an actuator 390, such as a piezoelectric ceramic, may be added below the gain chip 310. The dither control signal 138 is imposed on the bias current 132 applied to the gain chip 310, and the cavity length control signal 136 is imposed on the piezoelectric ceramic to change the deformation of the piezoelectric ceramic and thereby adjust the position of the cavity surface disposed at the gain chip 310, in order to adjust the cavity length of the external resonant cavity and thereby change the phase of the laser mode so that the output laser mode aligns with the wavelength selected by the wavelength selective component 320. Or, the cavity length control signal 136 is imposed on the bias current applied to the gain chip 310, and the dither control signal 138 is imposed on the piezoelectric ceramic.

In another variation, an actuator may be added below the wavelength selective component 320. The dither control signal 138 is imposed on the bias current 132 applied to the gain chip 310, and the cavity length control signal 136 is imposed on the actuator to control the actuator and thereby adjust the position of the cavity surface disposed at the wavelength selective component 320, in order to adjust the cavity length of the external resonant cavity and thereby change the phase of the laser mode so that the output laser mode aligns with the wavelength selected by the wavelength selective component. Or, the cavity length control signal 136 is imposed on the bias current 132 applied to the gain chip 310 or on the TEC 360, and the dither control signal 138 is imposed on the actuator below the wavelength selective component 320 to control the actuator and thereby cause the position of the wavelength selective component 320 to dither, in order to cause the cavity surface of the external resonant cavity to dither so that a dithering optical signal is outputted, thus facilitating the locking of the center wavelength of the output light beam.

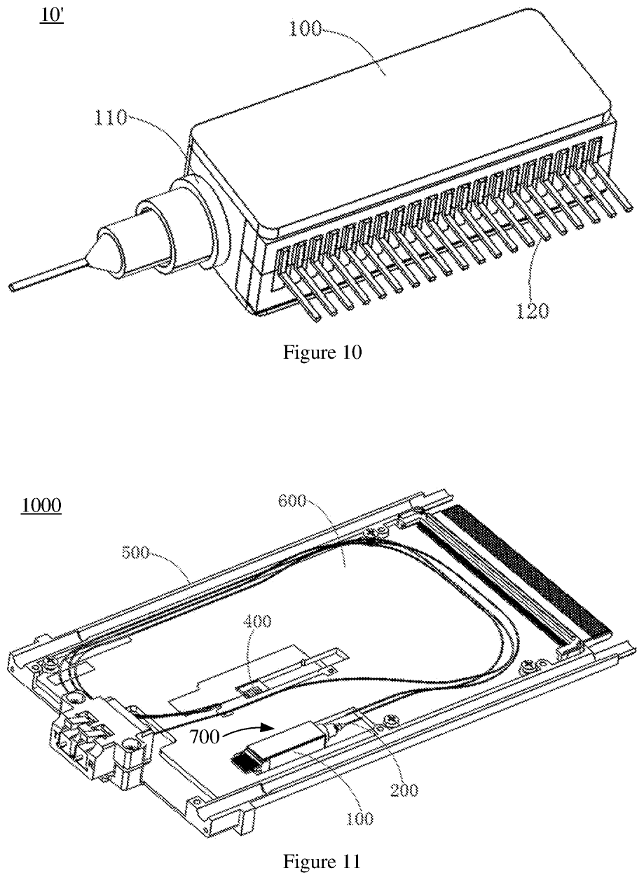

In all of the aforementioned example embodiments, as illustrated in FIG. 1, the electrical interface 120 of the sealed housing 100 may be disposed on an end surface of the sealed housing 100 opposing its optical interface 110. Or, as illustrated in FIG. 10, which is a diagram illustrating a package of a narrow linewidth external cavity laser 10′ according to another example embodiment of the present disclosure, the electrical interface 120 may alternatively be disposed on a side wall of the sealed housing 100. By disposing the electrical interface 120 on the side wall of the sealed housing 100, traces in the sealed housing 100 may be reduced so that the tracing space in the sealed housing 100 is reduced and the volume of the sealed housing 100 may be further reduced. The cavity surface of the external resonant cavity may be a standalone total reflection cavity mirror and/or partial reflection cavity mirror disposed on a side of the gain chip 310 away from the wavelength selective component 320 and a side of the wavelength selective component 320 away from the gain chip 310, respectively.

In all of the aforementioned example embodiments, the wavelength selective component 320 may employ an individual tunable filter component as illustrated in FIGS. 2 through 4 and FIG. 9, or employ a Vernier system made of two filter components as illustrated in FIGS. 5 through 8, or employ a wavelength selective component of another structure.

### Fifth Example Embodiment

FIG. 11 is a structural diagram illustrating an optical module 1000 according to a fifth example embodiment of the present disclosure. As illustrated in FIG. 11, the optical module 1000 includes a module outer housing 500, a circuit board 600, a silicon photonic integrated chip (PIC) 400, and a narrow linewidth laser 700. Here, the narrow linewidth laser 700 may be the narrow linewidth external cavity laser of any of the aforementioned example embodiments. A feedback assembly of the narrow bandwidth external cavity laser 700 is further integrated onto the silicon photonic integrated chip 400, and the feedback assembly includes a splitter component and a Monitor Photo Diode (MPD) and is used to provide feedback about the optical power and center wavelength outputted by the external cavity laser. In another example embodiment, the feedback assembly may be a Tap-PD or another form of combination of a splitter component and an MPD. The optical module 1000 uses the small package narrow linewidth external cavity laser of the aforementioned example embodiments of the present disclosure as the narrow linewidth laser 700. Therefore, the optical module 1000 may be made into a smaller size, and have a higher level of integration and a stabler output of narrow linewidth single mode laser light.

In another example embodiment, the housing 500 of the optical module 1000 is not limited to the housing structure illustrated in FIG. 11, and may alternatively use a package housing of another structure. In the fifth example embodiment, parts such as an optical modulator, and an optical receiver, etc. are integrated onto the silicon photonic integrated chip 400. In another example embodiment, the optical modulator and/or the optical receiver may alternatively be standalone parts in a free space.

The narrow linewidth external cavity laser of the example embodiments of the present disclosure may provide a high power narrow linewidth light source for a coherent optical module. The output optical power of the narrow linewidth external cavity laser may be higher than 12 dBm, which is higher than that of a distributed feedback laser (DFB) laser. The linewidth of the narrow linewidth external cavity laser may be smaller than or equal to 100 kHz, which is narrower than that of a DFB laser. The narrow linewidth external cavity laser is especially adapted for use in an optical module with silicon optic modulation, and is also adapted for use in other optical modules.

Embodiments of the present disclosure provide the following benefits. By having the dither control signal 138 act on the gain chip 310, the number of components in the external cavity is decreased, which significantly reduces the package size, resulting in a smaller volume. Also, insertion loss in the external cavity may be effectively reduced, thus decreasing the impact of insertion loss on the laser power and linewidth and resulting in stabler output laser light with a narrower linewidth.

The series of detailed descriptions above is only intended to provide specific descriptions of feasible embodiments of the present disclosure. They are not to be construed as limiting the scope of protection for the present disclosure; all equivalent embodiments or changes that are not detached from the techniques of the present disclosure in essence should fall under the scope of protection of the present disclosure.

What is claimed is:

1. A narrow linewidth external cavity laser comprising:
a sealed housing having disposed thereon an optical interface and an electrical interface;
an external resonant cavity disposed in the sealed housing; and
a gain chip and a tunable wavelength selective component that are disposed in the external resonant cavity,
wherein
the electrical interface is configured to receive an electrical signal comprising a drive signal, a wave selection signal, a cavity length control signal, and a dither control signal,
the drive signal is configured to drive the gain chip to emit a light beam, the light beam resonating in the external resonant cavity to produce a laser mode;
the wave selection signal is configured to tune the wavelength selective component to select a wavelength;
the cavity length control signal is configured to adjust an optical cavity length of the external resonant cavity so that the laser mode aligns with the wavelength selected by the wavelength selective component;
the dither control signal is configured to control the optical cavity length of the external resonant cavity to produce dither by adjusting an optical length of the gain chip, in order to lock a center wavelength of an output light beam of the external cavity laser.

2. The external cavity laser of claim 1, wherein
the drive signal comprises a bias current applied to the gain chip;
the dither control signal is superimposed on the bias current to adjust the bias current and thereby change the cavity length of the external resonant cavity to produce optical dither.

3. The external cavity laser of claim 2, further comprising an actuator;
wherein
the external resonant cavity includes a first cavity surface and a second cavity surface,
one of the cavity surfaces of the external resonant cavity being positioned above the actuator, and
the cavity length control signal is configured to control deformation of the actuator to change the position of the cavity surface on the actuator and thereby change the optical cavity length of the external resonant cavity.

4. The external cavity laser of claim 3, wherein the gain chip is disposed on the actuator, and
the cavity surface positioned above the actuator is the first cavity surface, which is formed by an end surface of the gain chip positioned above the actuator and away from the wavelength selective component.

5. The external cavity laser of claim 3, further comprising:
a coupling lens, the coupling lens being positioned along an output optical path of the external resonant cavity,
wherein the coupling lens comprises a flat surface near the external resonant cavity and a spherical or aspherical surface away from the external resonant cavity,
the coupling lens is disposed on the actuator, and
the cavity surface positioned above the actuator is the second cavity surface serving as an output cavity surface of the external resonant cavity, and the cavity surface is formed by the flat surface of the coupling lens.

6. The external cavity laser of claim 3, further comprising:
an isolator positioned along the output optical path of the external resonant cavity,
wherein the isolator is disposed on the actuator, and
the cavity surface positioned above the actuator is the second cavity surface serving as an output cavity surface of the external resonant cavity, and the cavity surface is formed by a flat surface of the isolator near the external resonant cavity.

7. The external cavity laser of claim 3, wherein the actuator comprises one of a piezoelectric component, a MEMS, or a linear motor.

8. The external cavity laser of claim 2, further comprising:
a cavity length adjusting component disposed in the external resonant cavity,
wherein the cavity length control signal is configured to control the cavity length adjusting component to change the optical cavity length of the external resonant cavity.

9. The external cavity laser of claim 8, wherein the cavity length adjusting component comprises one of a thermo-optical component, an acousto-optical component, a magnetic-optical component, an electro-optical component, or a liquid crystal assembly.

10. The external cavity laser of claim 8, wherein the cavity length adjusting component is disposed between the wavelength selective component and a cavity surface of the external resonant cavity,
the cavity length adjusting component comprises two opposing flat surfaces, the cavity surface of the external resonant cavity being disposed on the flat surface of the cavity length adjusting component away from the wavelength selective component.

11. The external cavity laser of claim 1, wherein the sealed housing is smaller than or equal to 0.3 cm³ in volume.

12. A narrow linewidth external cavity laser comprising:
a sealed housing having disposed thereon an optical interface and an electrical interface;
an external resonant cavity disposed in the sealed housing; and
a gain chip and a tunable wavelength selective component that are disposed in the external resonant cavity,
wherein
the electrical interface is configured to receive an electrical signal comprising a drive signal, a wave selection signal, a cavity length control signal, and a dither control signal,
the drive signal is configured to drive the gain chip to emit a light beam, the light beam resonating in the external resonant cavity to produce a laser mode;
the wave selection signal is configured to tune the wavelength selective component to select a wavelength,
the cavity length control signal is configured to adjust an optical cavity length of the external resonant cavity so that the laser mode aligns with the wavelength selected by the wavelength selective component,
the dither control signal is configured to control the optical cavity length of the external resonant cavity to produce dither in order to lock the center wavelength of an output light beam, and
the cavity length control signal is configured to adjust the optical cavity length of the external resonant cavity by adjusting an optical length of the gain chip.

13. The external cavity laser of claim 12, wherein
the drive signal comprises a bias current applied to the gain chip;
the cavity length control signal is superimposed on the bias current to adjust the bias current and thereby change the optical length of the gain chip in order to adjust the optical cavity length of the external resonant cavity.

14. The external cavity laser of claim 12, further comprising:
a thermoelectric cooler (TEC) disposed in the sealed housing, and the gain chip being disposed on the TEC,
wherein the cavity length control signal is configured to control the temperature of the TEC to adjust the optical length of the gain chip and thereby adjust the optical cavity length of the external resonant cavity.

15. The external cavity laser of claim 12, wherein the drive signal comprises a bias current applied to the gain chip, and
the dither control signal is superimposed on the bias current to adjust the bias current and thereby change an optical length of the gain chip in order to produce optical dither.

16. The external cavity laser of claim 12, further comprising:
an actuator, one cavity surface of the external resonant cavity being disposed on the actuator,
wherein the dither control signal is configured to control the deformation of the actuator to cause the cavity surface on the actuator to dither.

17. The external cavity laser of claim 12, further comprising:
a cavity length dither component disposed in the external resonant cavity,
wherein the dither control signal controls the cavity length dither component to cause optical dither in the external resonant cavity.

18. The external cavity laser of claim 17, wherein the cavity length dither component comprises one of an acousto-optical component, a magnetic-optical component, an electro-optical component, or a liquid crystal assembly.

19. The external cavity laser of claim 17, wherein the cavity length dither component is disposed between the wavelength selective component and a cavity surface of the external resonant cavity, and
the cavity length dither component comprises two opposing flat surfaces, the cavity surface of the external resonant cavity being disposed on the flat surface of the cavity length dither component away from the wavelength selective component.

20. An optical module, wherein the optical module comprises the external cavity laser of claim 1 or 12.
